(19) United States
(12) Patent Application Publication
(10) Pub. No.: US 2026/0360176 A1
(43) Pub. Date: Nov. 12, 2026

(54) GENERATION OF DOCUMENTS WITH FEATURES FOR MACHINE VISION AND COMPUTER-CONTROLLED AUTOMATION

(71) Applicant: Elektrik App, Inc., Lindon, UT (US)

(72) Inventors: Mario Fernando Dealba, Lehi, UT (US); Isaac Duarte, Pleasant Grove, UT (US); Mitchell Caffey, Nacogdoches, TX (US); Charles Croffs, Provo, UT (US); Tyler Jensen, Salem, UT (US); Arianna Mahoney, Provo, UT (US); Nathan Petersen, Provo, UT (US); John Rowberry, Provo, UT (US); Samuel Phillip Swindler, Provo, UT (US)

(21) Appl. No.: 19/674,782

(22) Filed: May 12, 2026

Related U.S. Application Data
(60) Provisional application No. 63/804,534, filed on May 12, 2025.

(51) Int. Cl. G06V 30/41; G06F 30/12; G06V 10/82

(52) U.S. Cl. CPC G06V 30/41; G06F 30/12; G06V 10/82

(57) ABSTRACT

Operations can include: receiving an input object comprising a document; preprocessing the input object into at least one image-file configured such that, when rendered for display on the display device, would provide a second visual depiction of the electrical power system; identifying, using first computer vision, the plurality of glyphs in the image-file; identifying the electrical components in the image-file based on the identifying of the plurality of glyphs; identifying, using second computer vision, the plurality of connection-marks in the image-file; identifying the electrical connections based on the identifying of the plurality of connection-marks; generating an intermediate-representation for the electrical power system, the intermediate-representation for the electrical power system; and a second listing of material identifiers for the electrical connections; and generating, using the intermediate-representation, a report of the electrical power system.

### CROSS-REFERENCE TO RELATED APPLICATIONS

This application claims benefit of priority to U.S. Application No. 63/804,534, filed on May 12, 2025. The disclosure of the prior application is considered part of (and is incorporated by reference in) the disclosure of this application.

The present document relates to machine vision for automatic analysis of visual elements of engineering drawings.

### BACKGROUND

Computer vision tasks include processes for devices that include acquiring, processing, analyzing, and understanding digital images, and extraction of high-dimensional data from the real world in order to produce numerical or symbolic information, e.g. in the form of decisions. Image processing can include disentangling of symbolic information from image data using.

Material take off (MTO) is a term used in engineering and construction, and refers to a list of materials with quantities and types (such as specific grades of steel) that are required to build a designed structure or item. The list of required materials for construction is sometimes referred to as the material take off list (MTOL).

### SUMMARY

Computer vision and machine learning can be used to analyze human-readable documents that define a manufacturing or construction project. Then, a computer system can select specific materials needed for the manufacturing or construction, and present the selected materials to human or computer-controlled recipients. The computer-controlled recipients can engage automation to prepare the materials for use.

In some aspects, the techniques described herein relate to a system including: one or more processors; and memory storing instructions that, when executed by the one or more processors, cause the one or more processors to perform operations including: receiving an input object including a document configured such that, when rendered for display on a display device, would provide a visual depiction an electrical power system, the visual depiction including: a plurality of glyphs that each represent an electrical component; and a plurality of connection-marks that each represent an electrical connection between at least two of the plurality of electrical components; preprocessing the input object into at least one image-file configured such that, when rendered for display on the display device, would provide a second visual depiction of the electrical power system; identifying, using first computer vision, the plurality of glyphs in the image-file; identifying the electrical components in the image-file based on the identifying of the plurality of glyphs; identifying, using second computer vision, the plurality of connection-marks in the image-file; identifying the electrical connections based on the identifying of the plurality of connection-marks; generating, based on the identifying of the electrical components and based on the identifying of the electrical connections, an intermediate-representation for the electrical power system, the intermediate-representation for the electrical power system, the intermediate-representation including: a first listing of material identifiers for the electrical components; and a second listing of material identifiers for the electrical connections; and generating, using the intermediate-representation, a report of the electrical power system.

In some aspects, the techniques described herein relate to a system, wherein the report includes a takeoff document that records the first listing of material identifiers, the second listing of material identifiers, an installation information specifying assembly of the electrical power system using the first listing and the second listing.

In some aspects, the techniques described herein relate to a system, wherein the report includes computer-readable instructions that, when executed by one or more printing systems, cause the printing systems to print package labels for packages configured to store first materials of the first listing of material identifiers and second materials of the second listing of material identifiers.

In some aspects, the techniques described herein relate to a system, wherein the report further includes computer-readable instructions that, when executed by a material-handling system, cause the material-handling system to engage material handlers to: pack, into packages, first materials of the first listing of material identifiers and second materials of the second listing of material identifiers; and apply the package labels to the packages.

In some aspects, the techniques described herein relate to a system, wherein the report further includes computer-readable instructions that, when executed by a material-loading system, cause the material-loading system to load one or more shipping containers with the packages in an order determined based on an order in which the store first materials of the first listing of material identifiers and second materials of the second listing of material identifiers are configured to be assembled into the electrical power system.

In some aspects, the techniques described herein relate to a system, wherein the operations further include rendering at least one of the group consisting of i) the document, and ii) the image-file.

In some aspects, the techniques described herein relate to a system, wherein the operations are free of rendering the document and free of rendering the image-file.

In some aspects, the techniques described herein relate to a system, wherein preprocessing the input object into at least one image-file includes at least one of the group consisting of i) converting gradient information to monochromatic information, ii) noise reduction, iii) data compression, iv) data decompression; and v) contrast adjustment.

In some aspects, the techniques described herein relate to a system, wherein identifying, using first computer vision, the plurality of glyphs in the image-file includes use of a convolutional neural network.

In some aspects, the techniques described herein relate to a system, wherein identifying, using second computer vision, the plurality of connection-marks in the image-file includes: generating a stripped-image-file by removing the plurality of glyphs from the image-file; identifying contours in the stripped-image-file; identifying the plurality of connection-marks in the image-file based on the identifying of the contours in the stripped-image-file.

In some aspects, the techniques described herein relate to a system including: one or more processors; and memory storing instructions that, when executed by the one or more processors, cause the one or more processors to perform operations including: receiving, through a graphical user interface (GUI), user input to a drafting program; generating, based on the user input to the drafting program, i) a document configured such that, when rendered for display on a display device, would provide a visual depiction an electrical power system, and ii) a drawing-data-object storing electrical components and electrical connections of the electrical power system; generating, based on the electrical components and based on the electrical connections, an intermediate-representation for the electrical power system, the intermediate-representation for the electrical power system including: a first listing of material identifiers for the electrical components; and a second listing of material identifiers for the electrical connections; and generating, using the intermediate-representation, a report of the electrical power system.

In some aspects, the techniques described herein relate to a system, wherein the report includes a takeoff document that records the first listing of material identifiers, the second listing of material identifiers, an installation information specifying assembly of the electrical power system using the first listing and the second listing.

In some aspects, the techniques described herein relate to a system, wherein the report includes computer-readable instructions that, when executed by one or more printing systems, cause the printing systems to print container labels for containers configured to store first materials of the first listing of material identifiers and second materials of the second listing of material identifiers.

In some aspects, the techniques described herein relate to a system, wherein the report further includes computer-readable instructions that, when executed by a material-handling system, cause the material-handling system to engage material handlers to: pack, into packages, first materials of the first listing of material identifiers and second materials of the second listing of material identifiers; and apply the container labels to the containers.

In some aspects, the techniques described herein relate to a system, wherein the report further includes computer-readable instructions that, when executed by a material-loading system, cause the material-loading system to load one or more shipping containers with the packages in an order determined based on an order in which the store first materials of the first listing of material identifiers and second materials of the second listing of material identifiers are configured to be assembled into the electrical power system.

In some aspects, the techniques described herein relate to a system for automatic conversion of engineering drawings into takeoff documents.

In some aspects, the techniques described herein relate to a method including: receiving, by computing hardware, an input object including a document configured such that, when rendered for display on a display device, would provide a visual depiction an electrical power system, the visual depiction including: a plurality of glyphs that each represent an electrical component; and a plurality of connection-marks that each represent an electrical connection between at least two of the plurality of electrical components; preprocessing, by computing hardware, the input object into at least one image-file configured such that, when rendered for display on the display device, would provide a second visual depiction of the electrical power system; identifying, using first computer vision, the plurality of glyphs in the image-file; identifying the electrical components in the image-file based on the identifying of the plurality of glyphs; identifying, using second computer vision, the plurality of connection-marks in the image-file; identifying the electrical connections based on the identifying of the plurality of connection-marks; generating, by computing hardware, based on the identifying of the electrical components and based on the identifying of the electrical connections, an intermediate-representation for the electrical power system, the intermediate-representation for the electrical power system, the intermediate-representation including: a first listing of material identifiers for the electrical components; and a second listing of material identifiers for the electrical connections; and generating, by computing hardware, using the intermediate-representation, a report of the electrical power system.

In some aspects, the techniques described herein relate to a method including: receiving, through a graphical user interface (GUI), user input to a drafting program; generating, based on the user input to the drafting program, i) a document configured such that, when rendered for display on a display device, would provide a visual depiction an electrical power system, and ii) a drawing-data-object storing electrical components and electrical connections of the electrical power system; generating, based on the electrical components and based on the electrical connections, an intermediate-representation for the electrical power system, the intermediate-representation for the electrical power system, the intermediate-representation including: a first listing of material identifiers for the electrical components; and a second listing of material identifiers for the electrical connections; and generating, by computing hardware, using the intermediate-representation, a report of the electrical power system.

In some aspects, the techniques described herein relate to non-transitory computer readable media tangibly storing instructions that, when executed by one or more processors, cause the processors to perform operations including: receiving, by computing hardware, an input object including a document configured such that, when rendered for display on a display device, would provide a visual depiction an electrical power system, the visual depiction including: a plurality of glyphs that each represent an electrical component; and a plurality of connection-marks that each represent an electrical connection between at least two of the plurality of electrical components; preprocessing, by computing hardware, the input object into at least one image-file configured such that, when rendered for display on the display device, would provide a second visual depiction of the electrical power system; identifying, using first computer vision, the plurality of glyphs in the image-file; identifying the electrical components in the image-file based on the identifying of the plurality of glyphs; identifying, using second computer vision, the plurality of connection-marks in the image-file; identifying the electrical connections based on the identifying of the plurality of connection-marks; generating, by computing hardware, based on the identifying of the electrical components and based on the identifying of the electrical connections, an intermediate-representation for the electrical power system, the intermediate-representation for the electrical power system, the intermediate-representation including: a first listing of material identifiers for the electrical components; and a second listing of material identifiers for the electrical connections; and generating, by computing hardware, using the intermediate-representation, a report of the electrical power system.

In some aspects, the techniques described herein relate to non-transitory computer readable media tangibly storing instructions that, when executed by one or more processors, cause the processors to perform operations including: receiving, through a graphical user interface (GUI), user input to a drafting program; generating, based on the user input to the drafting program, i) a document configured such that, when rendered for display on a display device, would provide a visual depiction an electrical power system, and ii) a drawing-data-object storing electrical components and electrical connections of the electrical power system; generating, based on the electrical components and based on the electrical connections, an intermediate-representation for the electrical power system, the intermediate-representation for the electrical power system, the intermediate-representation including: a first listing of material identifiers for the electrical components; and a second listing of material identifiers for the electrical connections; and generating, by computing hardware, using the intermediate-representation, a report of the electrical power system.

The devices, system, and techniques described herein may provide one or more of the following advantages. For example, a technical problem exists in the use of documents by computing devices. Many documents are formatted to be rendered, but do not store the information to be rendered in a format that is easily parsed or operated on by computing operations. This technology improves the technology of document processing via processes of computer vision. In one example, a contour-based link detection process is provided, which is particularly adapted to accurately identify electrical connections represented in rendered engineering drawings, but that is not sored in an easy-to-process format. This technology can, for example, identify non-electrical-link portions of an engineering drawing, and then accurately recognize only those remaining portions that represent electrical connections.

For example, a technical problem exists in the generation of electronically stored engineering drawings for projects to be constructed or manufactured. This document describes multiple solutions to overcome these technical problems. In some solutions, a first computer vision process is used to identify a subset of elements in the engineering drawing. Then, after removing those identified elements, a different computer vision process is used to identify a different subset of elements in the engineering drawings. By configuring the first computer vision process to be particularly adapted to identifying one kind of visual element, and the second computer vision process to be particularly adapted to identifying a different kind of visual element, this technology provides a solution to the computational analysis of engineering drawings. In some solutions, a drafting program is adapted to generate data that includes both a renderable portion to be rendered and understood by a human user and a computer-readable portion to be processed by computing hardware. By configuring the drafting program to create both types of data from the same types of input, the technology provides a solution to difficult-to-process engineering drawings by creating easy-to-process engineering drawings.

For example, a technical problem exists in the computer vision field in identifying connection marks in images or video. One reason recognition of connection marks is difficult is because connection marks may be discontinuous (e.g., dashes, dots, etc.). This document describes technology to that can overcome this problem by identifying aligned discontinuous contours as a single connection mark.

One reason recognition of connection marks is difficult is because lines depicting connections between symbols may intersect unrelated glyphs. This document describes technology to that can overcome this problem by stripping glyphs from consideration before attempting to identify connection marks.

One reason recognition of connection marks is difficult is because annotations (e.g., boxes) may present similar visual characteristics to connection marks even when they do not connect two or more glyphs as connection marks do. This document describes technology to that can overcome this problem by stripping glyphs from consideration before attempting to identify connection marks.

One reason recognition of connection marks is difficult is because connection marks may share some visual characteristics of glyphs that are not connection marks. For example, a glyph to represent electrical ground may include a vertical bar that has similar visual characteristics to a connection mark. This document describes technology to that can overcome this problem by stripping glyphs from consideration before attempting to identify connection marks.

The details of one or more implementations are set forth in the accompanying drawings and the description below. Other features, aspects and potential advantages will be apparent from the accompanying description and figures.

### DESCRIPTION OF DRAWINGS

FIG. 1 shows and example system for generating takeoff documents and computer code based on machine analysis of human-readable engineering drawings.

FIG. 2 shows a schematic diagram of example data that can be used.

FIG. 3 shows example architecture of computer systems that can be used.

FIG. 4 shows an example of an AI engine that can be used.

FIG. 5 shows an example process that can be used to generate documents and computer code from human-readable data.

FIG. 6 shows an example process that can be used to generate documents and computer code from a program that generates both human-readable and computer-readable data for engineering drawings.

FIG. 7 is a schematic diagram that shows an example of a computing device and a mobile computing device.

Like reference symbols in the various drawings indicate like elements.

### DETAILED DESCRIPTION

This document describes technology that can be used to automatically analyze engineering drawings, generate non-image-based representations of the drawings, and construct documents and/or computer automation to assemble the components needed to create the subject of the engineering drawings. For example, a computer system can ingest Portable Document Format (PDF) files containing details plans for a solar power farm, and use computer vision and/or machine learning to parse the drawings into a structured data object representing the solar power farm. Then, using a database of available materials (e.g., particular cables, particular transformers), the computer system can generate a list of needed materials and their configurations (e.g., which components are connected to which). With this information, the computer system can generate reports for display to humans, and/or can generate computer code for automated devices. Those automated devices can be engaged to perform operations for the creation of the solar power farm, such as generating labels for boxes, automated loading of the boxes with the materials, and automated placement of the boxes into trucks and trailers in an order that makes needed materials available in the order they should be used.

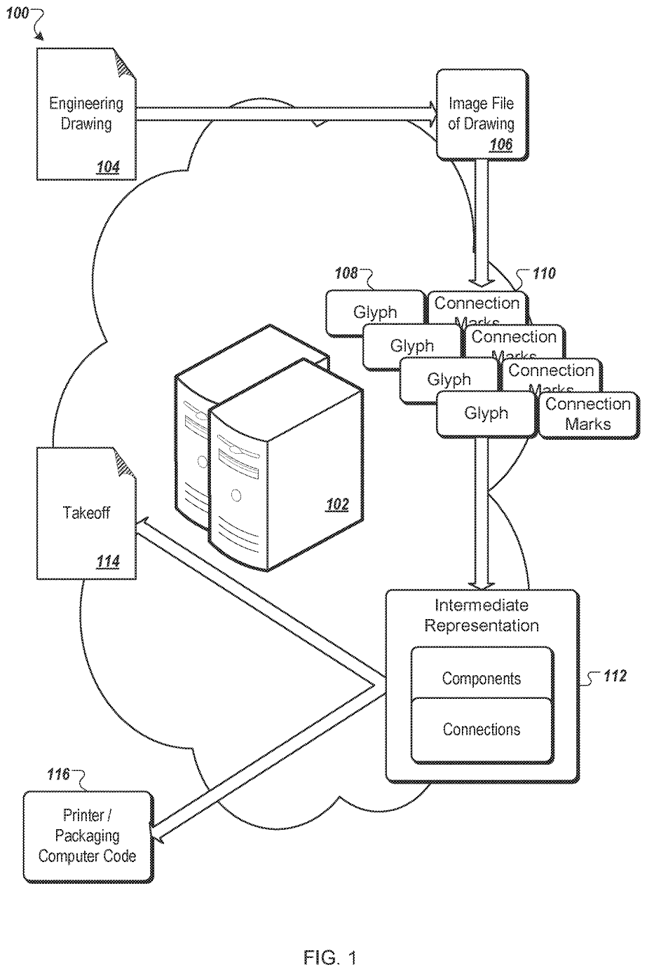

FIG. 1 shows an example system 100 for generating takeoff documents and computer code based on machine analysis of human-readable engineering drawings. In the system 100, a computer system 102 can automatically analyze engineering drawings 104 using computer vision and/or artificial intelligence procedures to extract computer-usable information. With this computer-usable information, various computer operations can be performed.

The computer system 102 can, for example, convert engineering drawings 104 into one or more image files 106. For example, the computer system 102 can programmatically generate one or more image files 106, which may or may not include rendering the image files on a screen or other display. The computer system 102 can then apply machine vision techniques to the one or more image files 106 to identify various elements of the image, including glyphs 108 and connection marks 110. The computer system 102 can use the glyphs 108 and connection marks 110 to create an intermediate representation 112 of the engineering drawing 104, including data for components (e.g., represented by the glyphs 108) and connections (e.g., represented by the connection marks 110). Then, the computer system 102 can produce outputs from the intermediate representation 112, which can include documents such as takeoff documents 114 and/or computer code 116.

The computer system 102 can include one or more computing devices, including one or more physical or virtual servers, microservice-providing hardware, personal computers, etc. The computer system 102 can also include one or more networks, including but not limited to the Internet. In some implementations, the engineering drawing 104 can be received from a particular user's computer device, and the takeoff documents 114 and/or computer code 116 can be delivered to the same computer, although it will be appreciated that other configurations are possible.

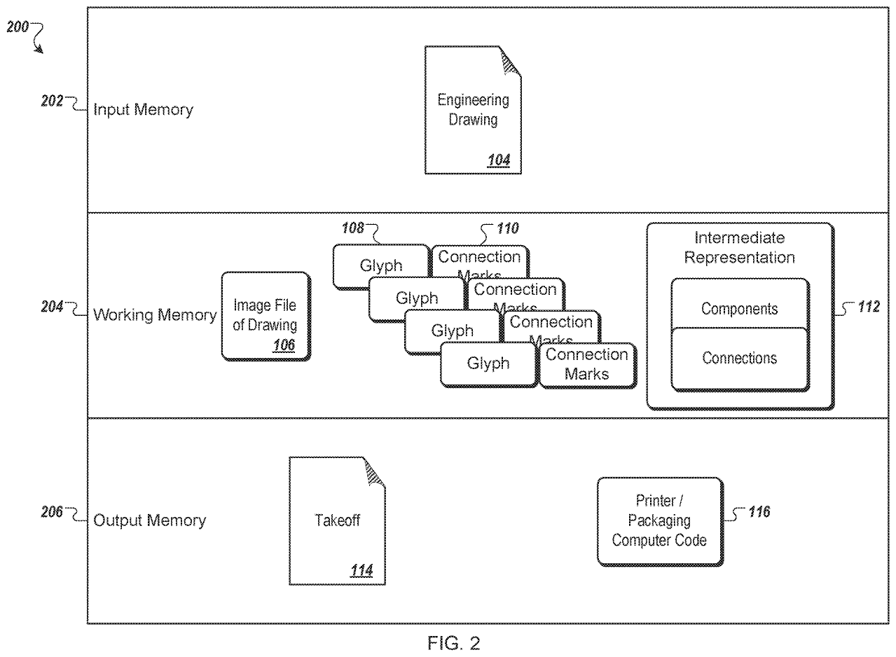

FIG. 2 shows a schematic diagram of example data 200 that can be used, for example by the system 100. In this example, the data 200 is organized into input memory 202, working memory 204, and output memory 206 to represent storage by the computer system 102 in various memory locations, which may be hardware based or based only on conception and/or addressing. Other configurations of memory and storage are possible.

The input memory 202 can receive and store the engineering drawing 104. The engineering drawings 104 can include one or more documents that, when rendered for display on a display device, would provide a visual depiction a product or product to be manufactured or constructed. One example of such a project is a solar electrical power system, which for clarity will be used as an example in this document. But other projects and product are possible, including other electrical-power related projects and non-electrical-power related projects and manufacturing (e.g., levy building, weather stations manufacturing and installation, wide-area network roll outs, livestock-management installations). In some implementations, the engineering drawings can include files in PDF format, although any other technologically-appropriate format may be used.

The visual depictions of the engineering drawings 104 can include various components that, by convention or as described in a legend, identify various components of a project or product. Some of these elements can include glyphs (e.g., one or groups of letters, shapes) that each represent an electrical component. For example, well-known glyphs can be used to represent transformers, electrical switches, circuit breakers, etc. Alternatively, custom glyphs may be used in the engineering drawings 104.

The visual depictions of the engineering drawings 104 can include various components that that, by convention or as described in a legend, identify various electrical connections between two or more of the electrical components. For example connection-marks such as lines (e.g., solid, dashed, dotted) with various properties (e.g., colors, line widths) can be used. For example, connection-marks such as jumps (e.g., pairs of circled letters) can be used to indicate a connection that would be messy or confused if represented by a line.

The one or more image files 106 can be configured such that, when rendered for display on a display device, would provide a second visual depiction of the electrical power system. For example, the engineering drawing 104 and the one or more image files 106 can show the same electrical power system, but with different visual representations. This may be caused, for example, by preprocessing by the computer system 102 of the one or more image files 106 to improve the accuracy of machine vision. This may be caused, for example, by editing by the computer system 102 of the one or more image files 106 to change one kind of glyph and/or connection-marks. For example, if two visually-similar glyphs are used in the engineering drawing 104, the computer system 102 can edit the one or more image files 106 to change the two glyphs to more visually distinct glyphs.

The working memory 204 can store data recording the glyphs 108 and connection marks 110. For example, computer system 102 can apply computer vision to the one or more image files 106 to analyze, parse, or extract information about the glyphs 108 and connection marks 110. This information can be formatted into an appropriate format such as a structured or unstructured data object (e.g., JavaScript Object Notation aka JSON object, Extensible Markup Language aka XML object, Binary Large Object aka BLOb). As will be appreciated metadata, including unique identifiers, may be used to aid organization and searching of the glyphs 108 and connection marks 110.

The working memory 204 can store the intermediate representation 112. For example, the computer system 102 can generate the intermediate representations 112 using the glyphs 108 to identify components represented by the glyphs 108, and store those components in the intermediate representation 112. For example, the computer system 102 can generate the intermediate representation 112 using the connection marks 110 to identify connections between the components and store those connections in the intermediate representation. As such, the intermediate representation 112 for the electrical power system can include a first listing of material identifiers for the electrical components and a second listing of material identifiers for the electrical connections.

The output memory 206 can store and transmit data generated by the computer system 102. For example, the output memory 206 can store and output a report that includes the takeoff document 114. The takeoff document 114 can be configured to record the first listing of material identifiers, the second listing of material identifiers, an installation information specifying assembly of the electrical power system using the first listing and the second listing. Additional information can be included such as instructions for installation, packaging information for the materials, etc.

For example, the output memory 206 can store and output the same or a different report that includes the computer code 116. The computer code 116 can include computer-readable instructions for computer devices and/or automation devices. These computer-readable instructions can be used to engage automation that senses and/or moves physical objects.

For example, the computer-readable instructions, when executed by one or more printing systems, can cause the printing systems to print package labels for packages. These packages can be configured to store first materials of the first listing of material identifiers and second materials of the second listing of material identifiers. In this way, automatic labeling of packages (e.g., cardboard boxes, bags, totes) may be advantageously provide based on computer processing of the data of the system 100.

For example, the computer-readable instructions, when executed by a material-handling system, can cause the material-handling system to engage material handlers to perform various operations. These operations can include packing into packages, first materials of the first listing of material identifiers and second materials of the second listing of material identifiers. These operations can include applying the package labels to the packages. In this way, automatic packing of packages with proper labels may be advantageously provided based on computer processing of the data of the system 100.

For example, the computer-readable instructions, when executed by a material-loading system, can cause the material-loading system to load one or more shipping containers (e.g., encapsulated cargo container, delivery van, wooden pallet) with the packages in an order determined based on an order in which the store first materials of the first listing of material identifiers and second materials of the second listing of material identifiers are configured to be assembled into the electrical power system. For example, if the first operation of installing the electrical power system requires installation of a junction box, the material-loading system can be instructed to load a container with the junction box and associated tools last, so that it is the first box available when the last shipping container is opened. In this way, automatic sorting and staging of properly labeled packages can be advantageously provided based on computer processing of data of the system 100.

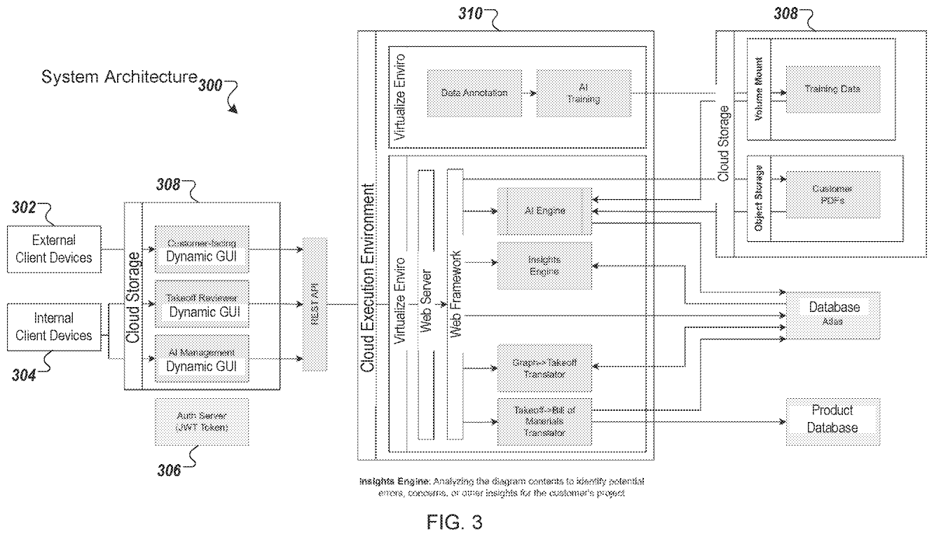

FIG. 3 shows example architecture 300 of computer systems that can be used. For example, the computer system 102 can use the architecture 300.

The architecture 300 can include external client devices 302 and/or internal client devices 304. These devices can include desktop or laptop computers, phones, tablets, etc. that can receive and provide user input and output. In various configurations, the system 100 may be available only to users that are internal to an organization (e.g., salespeople, installers), in which case the external client devices 302 may or may not be used. In various configurations, the system 100 may be available as self-service only to external users that are external to an organization (e.g., system purchasers), in which case the internal client devices 304 may or may not be used.

The architecture 300 can include an authentication server 306. The authentication server can, for example, maintain lists of authorized users, devices, network address, etc. Then, when a user, device, resource at a network address, etc. wishes to communicate with other elements o the architecture 300, the authentication sever can authorize them, or not. For example, the authentication server 306 can issue the user, device, or resource an authorization token.

The architecture 300 can include cloud storage 308. The cloud storage 308 can store elements for use in the architecture such as dynamic GUI information, training data and customer files, a database of products and information (e.g., atlases, dictionaries) about the products, etc.

The architecture 300 can include a cloud execution environment 310. The cloud execution environment can execute components of the architecture 300 in real or virtual environments. For example, a virtualization environment can host a web server with one or more web frameworks to execute various artificial intelligence (AI) engines, translators, etc.

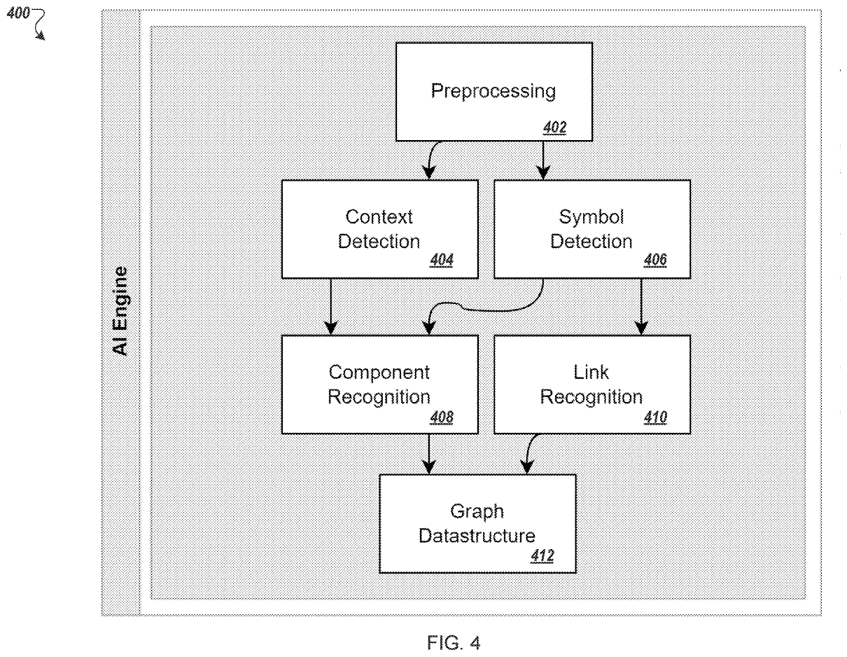

FIG. 4 shows an example of an AI engine 400 that can be used. For example, the AI engine 400 can be used by the computer system 102 in performing the processes 500 and/or 600. The AI engine 400 can be hosed, for example, in a virtualization environment with a web server with one or more web frameworks in the cloud execution environment 310.

The AI engine 400 can include a preprocessing module 402. For example, the preprocessing module 402 can operate on the engineering drawings 104 to output the one or more image files 106.

The AI engine 400 can include a context detection module 404 that operates with the output of the preprocessing module 402. For example, the context detection module 404 can operate on the one or more image files 106 to identify contextual information such as schedules, tables, and other specifications in the one or more image files 106.

The AI engine 400 can include a symbol detection module 406 that operates with the output of the preprocessing module 402. For example, the symbol detection module 406 can operate on the one or more image files 106 to identify the glyphs 108 and the connection marks 110.

The AI engine 400 can include a component recognition module 408 that operates with the output of the context detection module 404 and the symbol detection module 406. For example, the component recognition module 408 can operate on the contextual information, the glyphs 108, and/or the connection marks 110 to produce an identifier for a fully-specified electrical component for an electrical power system.

The AI engine 400 can include a link recognition module 410 that operates with the output of the symbol detection module 406. For example, the link recognition module 410 can use the glyphs 108 and/or the connection marks 110 to determine which of the glyphs 108 are electrically connected with other instances of the glyphs 108.

The AI engine 400 can include a graph datastructure module 412 that operates with the output of the component recognition module 408 and the link recognition module 410. For example, the graph datastructure module 412 can operate on the identifiers for fully-specified electrical components for an electrical power system and on the determined electrical connections to generate the intermediate representation. This intermediate representation can include, for example, a data graph of nodes and edges, with the nodes representing the electrical components and the edges representing the electrical connections.

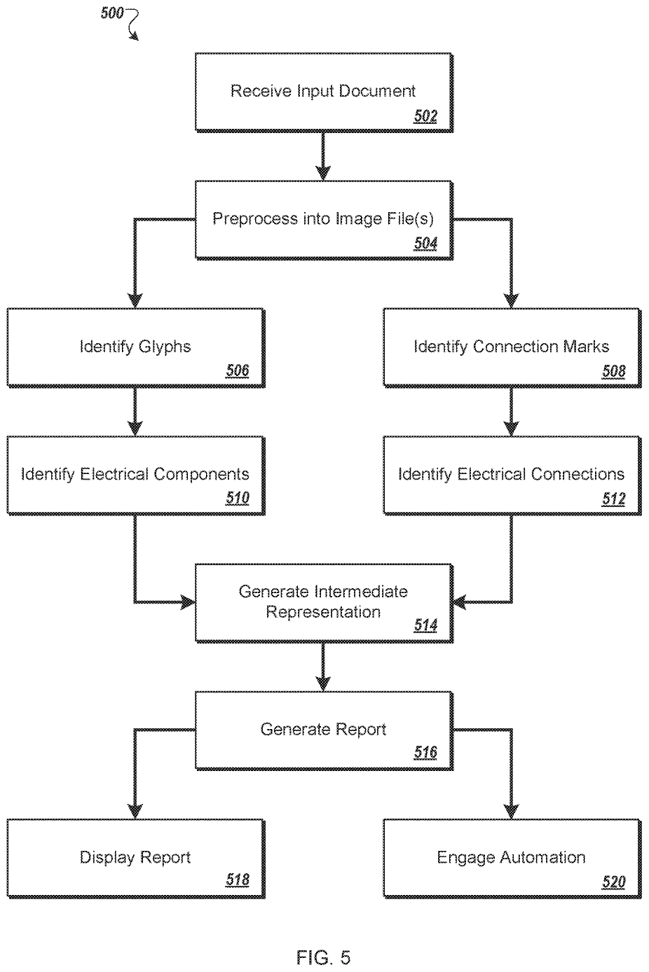

FIG. 5 shows an example process 500 that can be used to generate documents and computer code from human-readable data. For example, the computer system 102 can use the AI engine 400 in the architecture 300 to perform the process 500.

Input is received 502. For example, the computer system 102 can receive input from the external client devices 302 and/or the internal client devices 304. This input can include an input object that comprises one or more documents such as the engineering drawings 104. The document can include one or more files in a file format associated with electronic documents such as PDF, Tag Image File Format (TIFF), etc. The document may be created in software and saved, may be scanned into data format from a paper document, etc.

The input object is preprocessed 504. For example, the computer system 102 can use the AI engine 400 to preprocess the input object into one or more image files. The image files can include files in various appropriate formats such as TIFF, Joint Photographic Experts Group (JPEG), bitmap, Portable Network Graphics (PNG), custom formats, etc. In addition or in the alternative, derivative files can be created. For example, a bitmap can be created to be use as a masking filter to remove portions of the image files from consideration. Lower or higher resolution maps can be created to store data calculated from pixel or cell values of the image files, etc.

In some implementations, the preprocessing can include operations to make the image files more useful for machine vision operations. For example, gradient information can be converted to monochromatic information to increase the contrast of dark regions of the image, since markings on a document can be expected to not carry useful information in contrast information. Preprocessing operations can include none, one, or any, or all of i) converting gradient information to monochromatic information, ii) noise reduction, iii) data compression, iv) data decompression; v) contrast adjustment; and other operations.

Glyphs are identified 506. For example, the For example, the computer system 102 can use the AI engine 400 to use a first type of computer vision to identify the glyphs in the image-file. Various types of computer vision are possible. Sometimes, appropriate computer vision techniques are called Object Character Recognition (OCR). One type of computer vision that can be used for the first type of computer vision is sometimes known as You Only Live Once. The first type of computer vision can include operations that use a convolutional neural network. For example, a single and entire image can be provided to a convolutional neural network as a single input. The convolutional neural network can be configured to divide the input into regions, predict bounding boxes and probability in each region, and weigh each bounding box by predicted probability. In another example, subdivisions of various locations and scales can be supplied to one or more neural networks.

Connection marks are identified 508. For example, the computer system 102 can use the AI engine 400 to use a second type of computer vision to identify the plurality of connection-marks in the image-file. In other examples, the computer system 102 can use the first type of computer vision to identify the plurality of connection-marks in the image-file.

One type of computer vision that can be used to identify the plurality of connection-marks in the image-file is sometimes known as contour-based link detection. The computer vision can include identifying an image pattern indicative of a contour and/or (inner or outer) parameter of an element in an image. For example, the computer system 102 can generate a stripped-image-file by removing the plurality of glyphs from the image-file. Then the computer system 102 can identifying contours in the stripped-image-file. Because the stripped-image-file does not contain the glyphs from the image-file, these contours can be assigned to be electrical connections and not glyphs. The computer system 102 can therefore identify the plurality of connection-marks in the image-file based on the identifying of the contours in the stripped-image-file. In some cases, this can include combining discontinuous contours. For example, a dashed line may have a plurality of discontinuous contours that are aligned with each other, and thus the computer system 102 can detect these aligned discontinuous contours as a single connection-mark.

Electrical components are identified 510. For example, the computer system 102 can use the AI engine 400 to identify the electrical components in the image-file based on the identifying of the plurality of glyphs. The computer system 102 can identify the identity of each glyph, and look up a corresponding electrical component in a table of electrical components that is indexed by glyph identity.

Electrical connections are identified 512. For example, the computer system 102 can use the AI engine 400 to identify the electrical connections based on the identifying of the plurality of connection-marks. For example, the computer system 102 can identify two or more termination points of each connection-mark. Then, each glyph that is touching, nearest, or within a threshold distance of the termination point can be assigned as connected by the connection-mark.

An intermediate representation is generated 514. For example, the computer system 102 can use the AI engine 400 to generate, based on the identifying of the electrical components and based on the identifying of the electrical connections, an intermediate-representation for the electrical power system. For example, a graph of nodes and edges can be stored in computer memory by the computer system 102, with the nodes representing the electrical components and the edges representing the electrical connections.

A report is generated 516. For example, the computer system 102 can generate, using the intermediate-representation, a report of the electrical power system. This report can include, as described elsewhere, human-readable information that can be rendered for a user. This report can include, as described elsewhere, computer-readable instructions that, when executed, cause automation to be engaged.

The report is displayed 518. For example, the computer system 102 can provide the report to the appropriate external client devices 302 or internal client devices 304 for display to a user, e.g., on a screen.

Automation is engaged 520. For example, the computer system 102 can provide the computer-readable instructions to one or more device controllers that can execute the computer-readable instructions to engage automation.

Various examples of the process 500 can include different features. In some examples, the document and/or the image-file can be rendering on a display. In some examples, the document and the image-file is never rendered on the display and is, e.g., instead processed only in binary form.

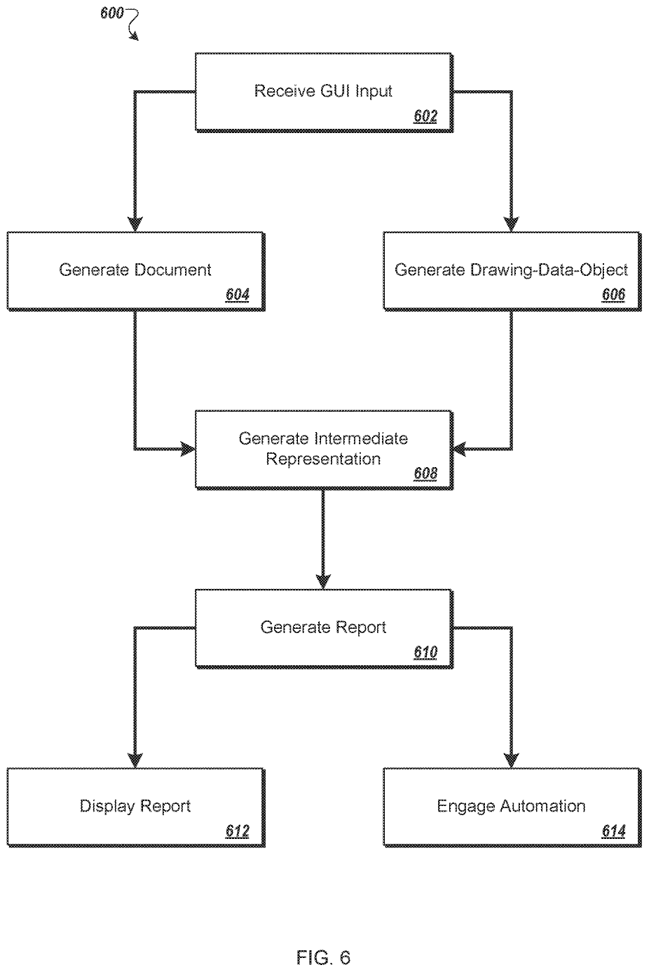

FIG. 6 shows an example process that can be used to generate documents and computer code from a program that generates both human-readable and computer-readable data for engineering drawings. For example, the computer system 102 can use the AI engine 400 in the architecture 300 to perform the process 600.

GUI input is received 602. For example, the computer system 102 can receive, through a GUI, user input to a drafting program for the drafting of an electrical power system. The user may be presented with a typical GUI for this task.

A document is generated 604. For example, based on the user's input, the drafting program may generate the engineering drawings 104. For example, the user can drag-and-drop elements for electrical component, click to identify electrical connections, etc. The computer system 102 can dynamically update the engineering drawings 104 as the user works, or when the user saves their work, etc.

A drawing-data-object is generated 606. For example, based on the user's input, the drafting program may generate the drawing-data-object to store information about the electrical components and electrical connections of the electrical power system. In some examples, the computer system 102 can embed this drawing-data-object in the engineering drawings 104. In some examples, the computer system 102 can store this drawing-data-object as a separate file in memory. In some implementations, creation of this drawing-data-object may be a native function of the drafting program. In some implementations, creation of this drawing-data-object may be performed based on one or more plug-ins that are loaded into the drafting program.

An intermediate representation is generated 514. For example, the computer system 102 can use the AI engine 400 to generate, based on the electrical components and based on the electrical connections of the drawing-data-object, an intermediate-representation for the electrical power system. For example, a graph of nodes and edges can be stored in computer memory by the computer system 102, with the nodes representing the electrical components and the edges representing the electrical connections.

A report is generated 516. For example, the computer system 102 can generate, using the intermediate-representation, a report of the electrical power system. This report can include, as described elsewhere, human-readable information that can be rendered for a user. This report can include, as described elsewhere, computer-readable instructions that, when executed, cause automation to be engaged.

The report is displayed 518. For example, the computer system 102 can provide the report to the appropriate external client devices 302 or internal client devices 304 for display to a user, e.g., on a screen.

Automation is engaged 520. For example, the computer system 102 can provide the computer-readable instructions to one or more device controllers that can execute the computer-readable instructions to engage automation.

Various examples of the process 606 can include different features. In some examples, only the drawing-data-object is created 606 and the document is not created 604.

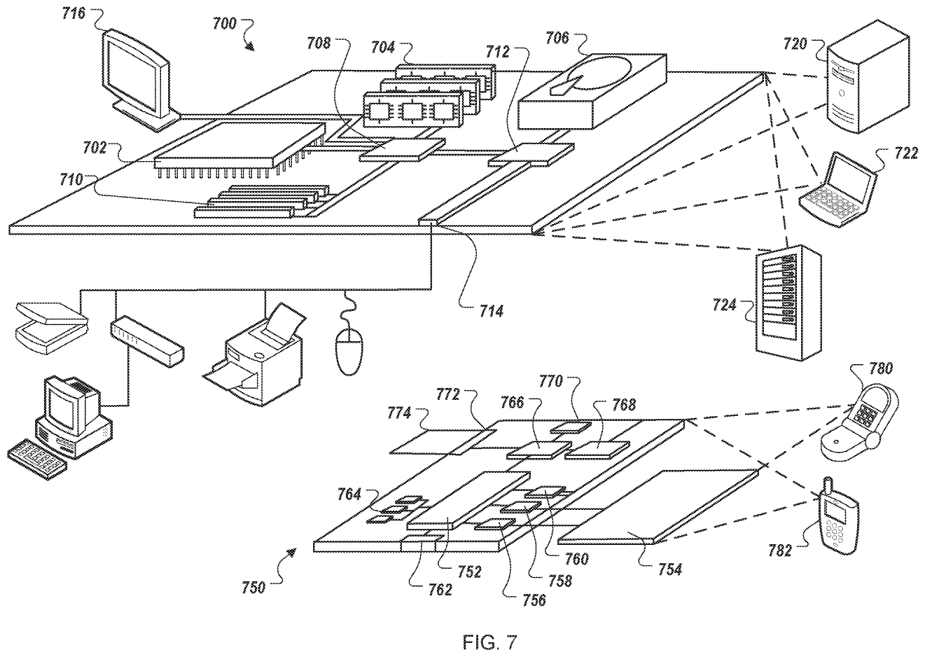

FIG. 7 shows an example of a computing device 700 and an example of a mobile computing device that can be used to implement the techniques described here. The computing device 700 is intended to represent various forms of digital computers, such as laptops, desktops, workstations, personal digital assistants, servers, blade servers, mainframes, and other appropriate computers. The mobile computing device is intended to represent various forms of mobile devices, such as personal digital assistants, cellular telephones, smart-phones, and other similar computing devices. The components shown here, their connections and relationships, and their functions, are meant to be exemplary only, and are not meant to limit implementations of the inventions described and/or claimed in this document.

The computing device 700 includes a processor 702, a memory 704, a storage device 706, a high-speed interface 708 connecting to the memory 704 and multiple high-speed expansion ports 710, and a low-speed interface 712 connecting to a low-speed expansion port 714 and the storage device 706. Each of the processor 702, the memory 704, the storage device 706, the high-speed interface 708, the high-speed expansion ports 710, and the low-speed interface 712, are interconnected using various busses, and can be mounted on a common motherboard or in other manners as appropriate. The processor 702 can process instructions for execution within the computing device 700, including instructions stored in the memory 704 or on the storage device 706 to display graphical information for a GUI on an external input/output device, such as a display 716 coupled to the high-speed interface 708. In other implementations, multiple processors and/or multiple buses can be used, as appropriate, along with multiple memories and types of memory. Also, multiple computing devices can be connected, with each device providing portions of the necessary operations (e.g., as a server bank, a group of blade servers, or a multi-processor system).

The memory 704 stores information within the computing device 700. In some implementations, the memory 704 is a volatile memory unit or units. In some implementations, the memory 704 is a non-volatile memory unit or units. The memory 704 can also be another form of computer-readable medium, such as a magnetic or optical disk.

The storage device 706 is capable of providing mass storage for the computing device 700. In some implementations, the storage device 706 can be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product can also contain instructions that, when executed, perform one or more methods, such as those described above. The computer program product can also be tangibly embodied in a computer-or machine-readable medium, such as the memory 704, the storage device 706, or memory on the processor 702.

The high-speed interface 708 manages bandwidth-intensive operations for the computing device 700, while the low-speed interface 712 manages lower bandwidth-intensive operations. Such allocation of functions is exemplary only. In some implementations, the high-speed interface 708 is coupled to the memory 704, the display 716 (e.g., through a graphics processor or accelerator), and to the high-speed expansion ports 710, which can accept various expansion cards (not shown). In the implementation, the low-speed interface 712 is coupled to the storage device 706 and the low-speed expansion port 714. The low-speed expansion port 714, which can include various communication ports (e.g., USB, Bluetooth, Ethernet, wireless Ethernet) can be coupled to one or more input/output devices, such as a keyboard, a pointing device, a scanner, or a networking device such as a switch or router, e.g., through a network adapter.

The computing device 700 can be implemented in a number of different forms, as shown in the figure. For example, it can be implemented as a standard server 720, or multiple times in a group of such servers. In addition, it can be implemented in a personal computer such as a laptop computer 722. It can also be implemented as part of a rack server system 724. Alternatively, components from the computing device 700 can be combined with other components in a mobile device (not shown), such as a mobile computing device 750. Each of such devices can contain one or more of the computing device 700 and the mobile computing device 750, and an entire system can be made up of multiple computing devices communicating with each other.

The mobile computing device 750 includes a processor 752, a memory 764, an input/output device such as a display 754, a communication interface 766, and a transceiver 768, among other components. The mobile computing device 750 can also be provided with a storage device, such as a micro-drive or other device, to provide additional storage. Each of the processor 752, the memory 764, the display 754, the communication interface 766, and the transceiver 768, are interconnected using various buses, and several of the components can be mounted on a common motherboard or in other manners as appropriate.

The processor 752 can execute instructions within the mobile computing device 750, including instructions stored in the memory 764. The processor 752 can be implemented as a chipset of chips that include separate and multiple analog and digital processors. The processor 752 can provide, for example, for coordination of the other components of the mobile computing device 750, such as control of user interfaces, applications run by the mobile computing device 750, and wireless communication by the mobile computing device 750.

The processor 752 can communicate with a user through a control interface 758 and a display interface 756 coupled to the display 754. The display 754 can be, for example, a TFT (Thin-Film-Transistor Liquid Crystal Display) display or an OLED (Organic Light Emitting Diode) display, or other appropriate display technology. The display interface 756 can comprise appropriate circuitry for driving the display 754 to present graphical and other information to a user. The control interface 758 can receive commands from a user and convert them for submission to the processor 752. In addition, an external interface 762 can provide communication with the processor 752, so as to enable near area communication of the mobile computing device 750 with other devices. The external interface 762 can provide, for example, for wired communication in some implementations, or for wireless communication in other implementations, and multiple interfaces can also be used.

The memory 764 stores information within the mobile computing device 750. The memory 764 can be implemented as one or more of a computer-readable medium or media, a volatile memory unit or units, or a non-volatile memory unit or units. An expansion memory 774 can also be provided and connected to the mobile computing device 750 through an expansion interface 772, which can include, for example, a SIMM (Single In Line Memory Module) card interface. The expansion memory 774 can provide extra storage space for the mobile computing device 750, or can also store applications or other information for the mobile computing device 750. Specifically, the expansion memory 774 can include instructions to carry out or supplement the processes described above, and can include secure information also. Thus, for example, the expansion memory 774 can be provide as a security module for the mobile computing device 750, and can be programmed with instructions that permit secure use of the mobile computing device 750. In addition, secure applications can be provided via the SIMM cards, along with additional information, such as placing identifying information on the SIMM card in a non-hackable manner.

The memory can include, for example, flash memory and/or NVRAM memory (non-volatile random access memory), as discussed below. In some implementations, a computer program product is tangibly embodied in an information carrier. The computer program product contains instructions that, when executed, perform one or more methods, such as those described above. The computer program product can be a computer-or machine-readable medium, such as the memory 764, the expansion memory 774, or memory on the processor 752. In some implementations, the computer program product can be received in a propagated signal, for example, over the transceiver 768 or the external interface 762.

The mobile computing device 750 can communicate wirelessly through the communication interface 766, which can include digital signal processing circuitry where necessary. The communication interface 766 can provide for communications under various modes or protocols, such as GSM voice calls (Global System for Mobile communications), SMS (Short Message Service), EMS (Enhanced Messaging Service), or MMS messaging (Multimedia Messaging Service), CDMA (code division multiple access), TDMA (time division multiple access), PDC (Personal Digital Cellular), WCDMA (Wideband Code Division Multiple Access), CDMA2000, or GPRS (General Packet Radio Service), among others. Such communication can occur, for example, through the transceiver 768 using a radio-frequency. In addition, short-range communication can occur, such as using a Bluetooth, WiFi, or other such transceiver (not shown). In addition, a GPS (Global Positioning System) receiver module 770 can provide additional navigation-and location-related wireless data to the mobile computing device 750, which can be used as appropriate by applications running on the mobile computing device 750.

The mobile computing device 750 can also communicate audibly using an audio codec 760, which can receive spoken information from a user and convert it to usable digital information. The audio codec 760 can likewise generate audible sound for a user, such as through a speaker, e.g., in a handset of the mobile computing device 750. Such sound can include sound from voice telephone calls, can include recorded sound (e.g., voice messages, music files, etc.) and can also include sound generated by applications operating on the mobile computing device 750.

The mobile computing device 750 can be implemented in a number of different forms, as shown in the figure. For example, it can be implemented as a cellular telephone 780. It can also be implemented as part of a smart-phone 782, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms machine-readable medium and computer-readable medium refer to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term machine-readable signal refers to any signal used to provide machine instructions and/or data to a programmable processor.

In some instances, machine instructions can include instructions for devices to engage motors, actuators, pumps, and other devices to move or manipulate physical objects. This can include, but is not limited to, robotic control of robotic devices (e.g., material-handling robotic arms with end-effectors), traversable devices capable of movement through the environment (e.g.,. automobiles, rovers, warehouse forklifts), and consumer electronics (e.g., garage door openers, home heating and cooling systems). In some implementations, machine instructions can include instructions for devices to operate sensors to generate sensor data based on sensing of physical phenomena. This can include, but is not limited to, light sensors, time-of-flight sensors, thermal sensors, acoustic sensors, strain gauges, etc.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (LAN), a wide area network (WAN), and the Internet.

The computing system can include clients and servers. A client and server are generally remote from each other and typically interact through a communication network. The relationship of client and server arises by virtue of computer programs running on the respective computers and having a client-server relationship to each other.

The foregoing detailed description and some embodiments have been given for clarity of understanding only. No unnecessary limitations are to be understood therefrom. It will be apparent to those skilled in the art that many changes can be made in the embodiments described without departing from the scope of the invention. For example, a different order and type of operations may be used to generate classifiers. Additionally, a bed system may aggregate output from classifiers in different ways. Thus, the scope of the present invention should not be limited to the exact details and structures described herein, but rather by the structures described by the language of the claims, and the equivalents of those structures. Any feature or characteristic described with respect to any of the above embodiments can be incorporated individually or in combination with any other feature or characteristic, and are presented in the above order and combinations for clarity only.

1. A system comprising:
one or more processors; and
memory storing instructions that, when executed by the one or more processors, cause the one or more processors to perform operations comprising:
receiving an input object comprising a document configured such that, when rendered for display on a display device, would provide a visual depiction of an electrical power system, the visual depiction comprising:
a plurality of glyphs that each represent an electrical component; and
a plurality of connection-marks that each represent an electrical connection between at least two of the plurality of electrical components;
preprocessing the input object into at least one image-file configured such that, when rendered for display on the display device, would provide a second visual depiction of the electrical power system;
identifying, using first computer vision, the plurality of glyphs in the at least one image-file;
identifying the electrical components in the at least one image-file based on the identifying of the plurality of glyphs;
identifying, using second computer vision, the plurality of connection-marks in the at least one image-file;
identifying the electrical connections based on the identifying of the plurality of connection-marks;
generating, based on the identifying of the electrical components and based on the identifying of the electrical connections, an intermediate-representation for the electrical power system, the intermediate-representation for the electrical power system comprising:
a first listing of material identifiers for the electrical components; and
a second listing of material identifiers for the electrical connections; and
generating, using the intermediate-representation, a report of the electrical power system.

2. The system of claim 1, wherein the report comprises a takeoff document that records the first listing of material identifiers, the second listing of material identifiers, and installation information specifying assembly of the electrical power system using the first listing and the second listing.

3. The system of claim 1, wherein the report comprises computer-readable instructions that, when executed by one or more printing systems, cause the one or more printing systems to print package labels for packages configured to store first materials of the first listing of material identifiers and second materials of the second listing of material identifiers.

4. The system of claim 3, wherein the report further comprises computer-readable instructions that, when executed by a material-handling system, cause the material-handling system to engage material handlers to:
pack, into the packages, first materials of the first listing of material identifiers and second materials of the second listing of material identifiers; and
apply the package labels to the packages.

5. The system of claim 4, wherein the report further comprises computer-readable instructions that, when executed by a material-loading system, cause the material-loading system to load one or more shipping containers with the packages in an order determined based on an order in which the first materials of the first listing of material identifiers and second materials of the second listing of material identifiers are configured to be assembled into the electrical power system.

6. The system of claim 1, wherein the operations further comprise rendering at least one of the group consisting of i) the document, and ii) the at least one image-file.

7. The system of claim 1, wherein the operations are free of rendering the document and free of rendering the at least one image-file.

8. The system of claim 1, wherein preprocessing the input object into the at least one image-file comprises at least one of the group consisting of i) converting gradient information to monochromatic information, ii) noise reduction, iii) data compression, iv) data decompression, and v) contrast adjustment.

9. The system of claim 1, wherein identifying, using first computer vision, the plurality of glyphs in the at least one image-file comprises use of a convolutional neural network.

10. The system of claim 1, wherein identifying, using second computer vision, the plurality of connection-marks in the at least one image-file comprises:
generating a stripped-image-file by removing the plurality of glyphs from the at least one image-file;
identifying contours in the stripped-image-file; and
identifying the plurality of connection-marks in the at least one image-file based on the identifying of the contours in the stripped-image-file.

11. A system comprising:
one or more processors; and
memory storing instructions that, when executed by the one or more processors, cause the one or more processors to perform operations comprising:
receiving, through a graphical user interface (GUI), user input to a drafting program;
generating, based on the user input to the drafting program, i) a document configured such that, when rendered for display on a display device, would provide a visual depiction of an electrical power system, and ii) a drawing-data-object storing electrical components and electrical connections of the electrical power system;
generating, based on the electrical components and based on the electrical connections, an intermediate-representation for the electrical power system, the intermediate-representation for the electrical power system comprising:
a first listing of material identifiers for the electrical components; and
a second listing of material identifiers for the electrical connections; and
generating, using the intermediate-representation, a report of the electrical power system.

12. The system of claim 11, wherein the report comprises a takeoff document that records the first listing of material identifiers, the second listing of material identifiers, and installation information specifying assembly of the electrical power system using the first listing and the second listing.

13. The system of claim 11, wherein the report comprises computer-readable instructions that, when executed by one or more printing systems, cause the one or more printing systems to print container labels for containers configured to store first materials of the first listing of material identifiers and second materials of the second listing of material identifiers.

14. The system of claim 13, wherein the report further comprises computer-readable instructions that, when executed by a material-handling system, cause the material-handling system to engage material handlers to:
pack, into the containers, first materials of the first listing of material identifiers and second materials of the second listing of material identifiers; and
apply the container labels to the containers.

15. The system of claim 14, wherein the report further comprises computer-readable instructions that, when executed by a material-loading system, cause the material-loading system to load one or more shipping containers with the containers in an order determined based on an order in which the first materials of the first listing of material identifiers and second materials of the second listing of material identifiers are configured to be assembled into the electrical power system.

16. (canceled)

17. A method comprising:
receiving, by computing hardware, an input object comprising a document configured such that, when rendered for display on a display device, would provide a visual depiction of an electrical power system, the visual depiction comprising:
a plurality of glyphs that each represent an electrical component; and
a plurality of connection-marks that each represent an electrical connection between at least two of the plurality of electrical components;
preprocessing, by computing hardware, the input object into at least one image-file configured such that, when rendered for display on the display device, would provide a second visual depiction of the electrical power system;
identifying, using first computer vision, the plurality of glyphs in the at least one image-file;
identifying the electrical components in the at least one image-file based on the identifying of the plurality of glyphs;
identifying, using second computer vision, the plurality of connection-marks in the at least one image-file;
identifying the electrical connections based on the identifying of the plurality of connection-marks;
generating, by computing hardware, based on the identifying of the electrical components and based on the identifying of the electrical connections, an intermediate-representation for the electrical power system, the intermediate-representation for the electrical power system comprising:
a first listing of material identifiers for the electrical components; and
a second listing of material identifiers for the electrical connections; and
generating, by computing hardware, using the intermediate-representation, a report of the electrical power system.

18-20. (canceled)

21. The method of claim 17, further comprising rendering at least one of the group consisting of i) the document, and ii) the at least one image-file.

22. The method of claim 17, wherein the report comprises computer-readable instructions that, when executed by one or more printing systems, cause the one or more printing systems to print package labels for packages configured to store first materials of the first listing of material identifiers and second materials of the second listing of material identifiers.

23. The method of claim 17, wherein preprocessing the input object into the at least one image-file comprises at least one of the group consisting of i) converting gradient information to monochromatic information, ii) noise reduction, iii) data compression, iv) data decompression, and v) contrast adjustment.

24. The method of claim 17, wherein identifying, using first computer vision, the plurality of glyphs in the at least one image-file comprises use of a convolutional neural network, and wherein identifying, using second computer vision, the plurality of connection-marks in the at least one image-file comprises:
generating a stripped-image-file by removing the plurality of glyphs from the at least one image-file;
identifying contours in the stripped-image-file; and
identifying the plurality of connection-marks in the at least one image-file based on the identifying of the contours in the stripped-image-file.
